(19) United States
(12) Patent Application Publication
(10) Pub. No.: US 2006/0115912 A1
(43) Pub. Date: Jun. 1, 2006

(54) Manufacturing method and luminance adjustment method of light emitting element array, exposure head, and electrophotographic apparatus

(75) Inventor: Kenichi Masumoto, Hirakata-shi (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/286,288

(22) Filed: Nov. 25, 2005

(30) Foreign Application Priority Data
Nov. 26, 2004 (JP) 2004-341707

(51) Int. Cl. H01L 21/00

(52) U.S. Cl. 438/22

(57) ABSTRACT

As for a light emitting array and an exposure head provided with a plurality of light emitting elements capable of emitting light by the supplying power respectively, the electrical stress is given only to the light emitting element selected based on the luminance of each light emitting element, whereby the luminance of the light emitting element is reduced. According to such configuration, it is possible to provide the light emitting array with the small light volume dispersion, and the exposure head, and the electrophotographic apparatus thereof.

### FIELD OF THE INVENTION

The invention relates to a light emitting element array and an exposure head that are provided with a plurality of light emitting elements capable of emitting light by supplying power respectively, a manufacturing method of the light emitting element array and the exposure head, a luminance adjustment method of the light emitting element array, and an electrophotographic apparatus with the exposure head.

### BACKGROUND OF THE INVENTION

An electrophotographic apparatus forms a latent image on a photoconductive drum, for example, by light emitted from an exposure head provided with a plurality of light emitting elements, and then forms an image on a paper based on the latent image. In such electrophotographic apparatus, each light volume of light emitted from the exposure head must be even so that thus formed image on the paper does not have density dispersion.

However, in LED (Light Emitting Device) generally used as the light emitting element, a light emitting area is formed by the PN junction. If the exposure head is formed by a plurality of elements disposed linearly and widely, the luminance dispersion becomes large caused by the manufacturing dispersion of the PN junction. Accordingly, the light volume dispersion is corrected by controlling the driving current provided to each light emitting element, and controlling the light emitting time, according to initial luminance values of each element obtained in advance.

On the other hand, there is a well known exposure head, as disclosed in Japan Patent Publication No. 2003-334990, that an organic electroluminescence element (organic EL element) is used as a light emitting element. Since the organic EL element is manufactured by means of a vapor deposition process that is able to obtain higher manufacturing accuracy in a wide area, it is well known that it is possible to reduce the light volume dispersion of a light volume of the exposure head is formed by the plural elements disposed linearly and widely. Besides, in the specification, the light volume indicates a physical quantity capable of specifying brightness of light, such as quantity of light, luminance, luminous intensity and luminous flux.

As described above, the reason that the light volume dispersion becomes small in the exposure head using the organic EL elements is a result that the manufacturing dispersion is small when the EL elements are formed. Even in case of using the organic EL element as the light emitting element, the exposure head for high resolution such as 2400 dpi (dot per inch) needs a microfabrication capability of disposing each element size of about 5 micrometers with about 10 micrometers pitch. When the size of each light emitting element is smaller, the size dispersion between the light emitting elements becomes larger relatively. This reflects on the light volume dispersion of the light emitting elements. Therefore, the light volume dispersion of the light emitting elements has to be corrected like the exposure head using the LED.

It often happens that the exposure head is provided with not only the light emitting elements, but also optical components, such as a lens for focusing light generated by each light emitting element on a surface of the photoconductive drum. In such configuration, as the light volume dispersion of the light emitted from the exposure head depends on not only the light volume dispersion of the light emitting elements, but also the optical characteristics of the optical components, the light volume correction, such as a driving current control and a lighting time control, is carried out based on the initial light volume value obtained through the optical components.

In order to correct the light volume dispersion, the exposure head is provided with a circuit for the light volume correction per light emitting element, but the circuit for the correction has a complicated circuit configuration to extend a possible range of the light volume correction. Where the exposure head is provided with a number of light emitting elements like the exposure head for the high resolution, there are problems such as increasing a space to mount the correction circuit, increasing assembly process steps of the exposure head, and the like.

On the other hand, if uniform organic EL element (light emitting element) and uniform optical components, of which the manufacturing accuracy are improved, are used instead of being provided with the correction circuit, it is possible to reduce the light volume dispersion of the light emitted from the exposure head. However, improving the manufacturing accuracy in the microfabrication is not preferable because the manufacturing cost increase instantly due to such improvement.

The above-mentioned Japan Patent Publication No. 2003-334990 discloses a technique for reducing the light volume dispersion of light emitting elements of the exposure head, wherein the light emitting elements of the exposure head are arranged so as to have approximately the same lighting count (lighting time), and have the same condition of the light volume degradation. However, when the exposure head is formed by a plurality of elements disposed linearly and widely as mentioned above, there is a possibility that the time-dependent behavior of the light volume degradation will not be the same on each element disposed on both sides. When each light emitting element used to the same exposure head has a different time dependency of the light volume degradation, even if the lighting count (the lighting time) is made to be identical approximately for every element, the light volume degradation cannot be corrected.

### SUMMARY OF THE INVENTION

The invention is proposed in view of the above-mentioned problems, and has objects of providing a light emitting element array and an exposure head capable of reducing the light volume dispersion by a simple configuration, and a manufacturing method and a light volume adjustment method thereof, and a suitable electrophotographic apparatus mounted the exposure head.

The invention adopts following means to achieve the above objects. The manufacturing method of the light emitting array in the invention is for forming the light emitting element array by integrating a plurality of light emitting elements that emit light by supplying power respectively, and comprises steps of measuring a luminance of each light emitting element, and giving a electrical stress only to the light emitting element selected based on the measured luminance for the duration corresponding to the selected element's luminance. Accordingly, it is possible to degrade selectively the luminance of the light emitting element in the light emitting element array.

In another view of the invention, it is possible to provide the luminance adjustment method of adjusting the luminance of the light emitting element array formed by integrating a plurality of light emitting elements that emit light by supplying power respectively. The luminance adjustment method comprises steps of measuring a luminance of each light emitting element, and degrading the luminance of the light emitting element selected based on the measured luminance by giving an electrical stress for the duration corresponding to the luminance only to the selected light emitting element. Accordingly it is possible to adjust the luminance of each light emitting element within a specific range.

In the above configuration, only the luminance of the light emitting element that is selected based on the measured luminance in the light emitting element array is degraded by giving a electrical stress, it is possible to obtain the light emitting element array having a small light volume dispersion.

The light emitting array manufactured by the above manufacturing method and the light emitting element array adjusted by the above luminance adjustment method has following features. That is to say, all the luminances of the light emitting elements in the light emitting element array when a same current is supplied to each the element is 90% and more of a maximum value of all the luminances. And a plurality of voltage drops on the light emitting elements in the light emitting element array when a same current is supplied to each the element is 110% and more of a minimum value of all the voltage drops. In here, the voltage drop indicates dropped voltage at each element under current application.

The light emitting element array mentioned above has following features. That is to say, when the same current is applied to each the light emitting element, a standard deviation of the voltage drops of all the elements divided by a mean value of the voltage drops is larger than a standard deviation of the luminances of all the elements divided by a mean value of the luminances.

The light emitting element array in the invention has a life of the element as well as the conventional light emitting element array, and has the small light volume dispersion. As a result, the manufacturing yield of the light emitting element array is improved. This makes it possible to perform the lower cost manufacturing as compared with the conventional light emitting element array. The use of the above-mentioned light emitting element array makes it possible to obtain an exposure head with the small light volume dispersion. In addition, the use of the exposure head can carry out the low-cost electrophotographic apparatus.

In still another view of the invention, it is possible to provide the exposure head for emitting light generated from a plurality of light emitting elements respectively. The exposure head comprises a storage unit configured to store light volume values of each emitted light, and an aging unit configured to giving an electrical stress corresponding to the light volume value stored in the storage unit to each light emitting element. The light volume value is mainly an initial light volume value of each emitted light measured after the exposure head was assembled, but it may be the light volume value after the light emitting elements worked as the exposure head for an arbitrary time. The light volume value to be stored may be an adjustment coefficient of each light emitting element when a specific light volume is as a standard.

The aging unit gives the light emitting element the electrical stress corresponding to the light volume value, for example, by controlling a drive circuit applying the electric power to the light emitting elements. At this time, the light volume of the light emitting element is degraded according to the electrical stress.

Therefore, it is possible in the above-mentioned configuration to perform the aging on each light emitting element mounted on the exposure head corresponding to the light volume values, and it is possible to reduce the light volume dispersion of each light emitting element mounted on the exposure head.

Instead of giving the electrical stress to all the light emitting elements, the aging unit preferably selects the light emitting element corresponding to the emitted light providing the light volume value larger than a reference light volume value set based on a specific light volume value, and gives the electrical stress only to the selected light emitting element. The specific light volume value can adopt any of a minimum light volume value on the exposure head, a predetermined light volume value, and a value not less than a predetermined light volume and nearest to the predetermined light volume value on the exposure head. For instance, it is configured that the reference light volume value is defined as 1.22 times the minimum light volume value on the exposure head, and the electrical stress is given only to the light emitting element corresponding to the emitted light providing the light volume more than the reference light volume value, and the light volume of the emitted light is degraded to be not more than the reference light volume value and not less than the minimum light volume value by the aging. Accordingly, in the exposure head after the aging, the light volumes of all the emitted lights belong to a range of ±10% of a median between the minimum light volume value and the reference light volume value.

Moreover, the aging unit may perform an accelerated aging in order to reduce the aging time.

The above-mentioned configuration further includes a light volume regulating unit configured to regulate the light volume of all the light emitting elements evenly based on the specific light volume value, so that it makes it further possible to perform the light volume regulation at one time over the whole of the exposure head of which light volume dispersion within elements is reduced by the aging. The light volume regulation unit shifts a specific quantity of the current or the voltage to be supplied to each light emitting element base on the specific light volume value over all the light emitting elements, or shifts a specific quantity of the lighting time over all the light emitting elements based on the specific light volume value, so that all the light emitting elements could be subjected to the light volume regulation with the same quantity respectively.

In also view of the invention, when the aging unit is configured to be provided to an outside of the exposure head, the other manufacturing method of the exposure head can be provided so that the aging unit performs the aging at the exposure head is assembled.

In case of the exposure head in the invention, since the aging can be performed respectively on the light emitting element selected based on the light volume of each emitted light, it is possible to obtain the exposure head with the small light volume dispersion with ease.

Since all the emitted lights of the aged exposure head provide the light volumes within the predetermined permissible range set based on the specific light volume value, the same regulation of the light volume is performed on all the light emitting elements based on the specific light volume value, and thereby all the light volumes of the exposure head can be regulated within the permissible range of desired light volume values easily. Therefore, a drive circuit does not require the correction circuit for correcting the light volumes of each light emitting element respectively, which is provided to the conventional exposure head, and it is possible to make the drive circuit for each light emitting element a simple configuration. In other words, as compared with the conventional exposure head, it is possible to downsize the exposure head in a simple manner.

On the other hand, the above-mentioned configuration can be applied to the electrophotographic apparatus for performing an image forming based on a latent image formed by the exposure head for emitting light generated from a plurality of light emitting elements respectively. In this case, the electrophotographic apparatus comprises the light volume regulating unit, and the light volume regulating unit performs the light volume regulation evenly on the light volumes of all the light emitting elements on the exposure head, according to need. Therefore, as well as the exposure head with the light volume regulating unit, it is further possible to perform the light volume regulation over the whole of the exposure head of which light volume dispersion was reduced by the aging.

When the light volume regulating unit is configured so as to regulate the light volumes of all the emitted lights based on the image forming result, such as a print density of a test pattern formed on a paper, as well as based on the specific light volume value, the light volume regulation can be performed considering the manufacturing dispersion, such as the exposure sensitivity of a photoconductor on which a latent image is formed.

In addition, the electrophotographic apparatus comprises the light volume detecting unit configured to detect the light volume value of each emitted light of the exposure head, and the aging unit configured to giving a electrical stress, which degrade the light volume value of a selected light emitting element, corresponding to the emitted light to the light emitting element selected based on the light volume value detected by the light volume detecting unit. Accordingly, even when the dispersion appears in the light volumes of each emitted light by working the exposure head of which light volume dispersion was reduced as the exposure head for an arbitrary time, the above-mentioned aging is performed on the respective light emitting elements of the exposure head properly, and the light volume dispersion can be reduced.

As described above, the electrophotographic apparatus in the invention, which is provided with the exposure head in the invention, can perform the light volume regulation with ease according to an optimum exposure light volume, even when the optimum exposure light volume (sensitivity) of the photoconductor varies respectively due to the manufacturing dispersion.

Moreover, the electrophotographic apparatus in the invention can perform the aging not only when the exposure head is assembled, but also when the exposure head is in use normally, so that the light volumes of the exposure head can be uniformed according to need.

The invention is disclosed here by reciting all the disclosure including the specification, the drawings, and the claims in Japan Patent Application No. 2004-341707 filed Nov. 26, 2004.

The disclosure, other objects, and characteristics of the invention are explained hereinafter according to attached drawings to provide the throughout understanding of the invention.

### BRIEF DESCRIPTION OF THE DRAWINGS

FIG. 1 is a sectional view of an exposure head of the invention.

FIG. 2 is a plane view of the exposure head of the invention.

FIG. 3 is a sectional view of a relevant part of the exposure head of the invention.

FIG. 4 is a graph showing a change of the luminance of an organic EL element along with a power supplying time.

FIG. 5 is a block diagram of the exposure head of the invention.

FIG. 6 is a flowchart in connection with the invention.

FIG. 7 is a flowchart in connection with the invention.

FIG. 8 is a flowchart in connection with the invention.

FIG. 9 is a flowchart in connection with the invention.

FIG. 10 is a flowchart in connection with the invention.

FIG. 11 is a diagram illustrating the accelerated aging.

FIG. 12 is a schematic functional block diagram of another modified embodiment of the invention.

FIGS. 13A and 13B are a diagram explaining a feature of the light emitting element after the aging.

FIGS. 14A to 14C are a diagram explaining the light volume regulation of the exposure head of the invention.

FIG. 15 is a schematic functional block diagram of the other modified embodiment of the invention.

FIG. 16 is a schematic functional block diagram of an electrophotographic apparatus of the invention.

FIGS. 17A to 17C are a diagram explaining the light volume regulation of the exposure head of the invention.

FIG. 18 is a schematic functional block diagram of the electrophotographic apparatus of the invention.

### DETAILED DESCRIPTION OF THE INVENTION

Embodiments of the invention are discussed here in details according to attached drawings.

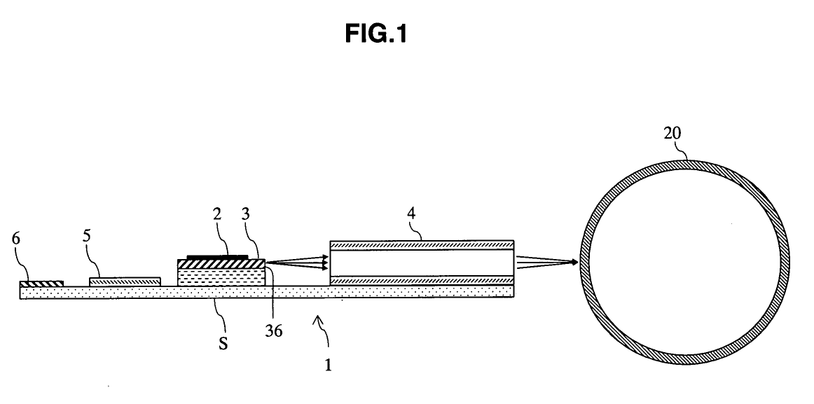

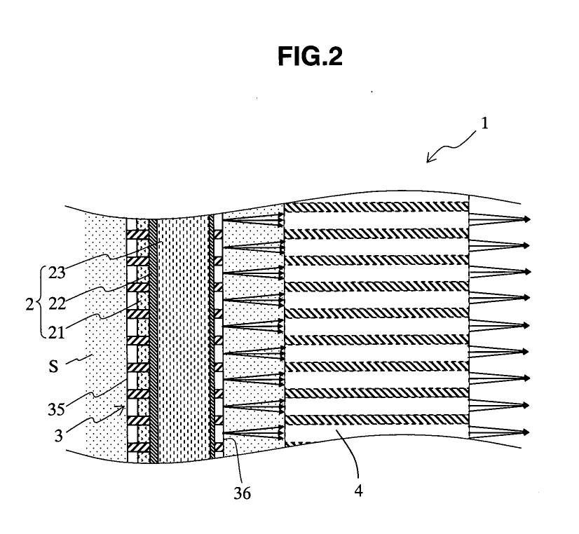

A basic structure of an exposure light of the invention is schematically illustrated according to a sectional view in FIG. 1 and a plane view of a relevant part in FIG. 2. FIG. 1 and FIG. 2 show examples of the exposure head structure suitable for the high resolution particularly, and the structure of the exposure head of the invention is not limited only to this structure.

As shown in FIG. 1, an exposure head 1 of the invention is provided with a light emitting element array 2, a light guide plate 3, and a lens array 4 on a substrate S made of glass, a metal and so. The light emitting element array 2 (which will be described as a light emitting element 2, according to need) is formed by a plurality of organic EL elements that are disposed linearly along a width direction of a photoconductor 20 on which a latent image is formed. The light guide plate 3 guides light from the light emitting element 2 to a direction of the photoconductor 20. The lens array 4 focuses a light emitted from the light guide plate 3 on the photoconductor 20.

The light guide plate 3 is a structure that a plurality of light guide paths 35 extended along a light emitting direction are placed in parallel to the width direction of the photoconductor 20, and the light emitting elements 2 are formed on an upper surface of each light guide path 35. In order to even the upper surface of the light guide plate 3, a material with a refractive index higher than that of the light guide path 35 is filled in between the light guide paths 35. According to such configuration, the lights came from the light emitting elements 2 are transmitted inside the light guide path 35 by means of total reflection.

A light outlet 36 of each light guide path 35 is formed in a square having a cross section corresponding to the resolution of the exposure head 1. And the light emitted from the light emitting element 2 on the upper surface of the light guide path 35, of which area is larger than that of the light outlet 36, can be collected. Therefore, in case of the exposure head for high resolution such as 2400 dpi, for example, it is possible to send to the lens array 4 the light with light volume enough to expose the photoconductor 20.

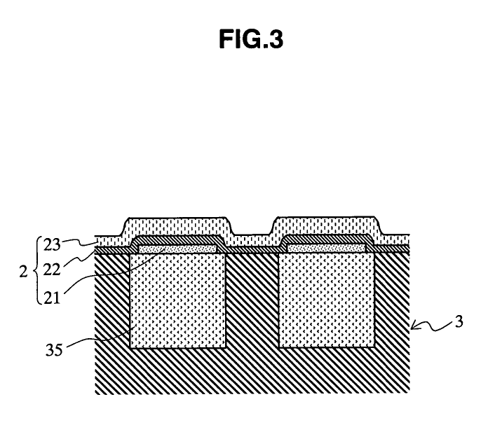

As shown in the sectional view of the relevant part in FIG. 3, the light emitting element 2 comprising a lower layer transparent electrode 21 made of ITO (Indium Tin Oxide) and formed on each light guide path 35 being separated electrically from the other electrode; an organic luminous layer 22 made of 8-quinolinol aluminum complex and formed as a common layer on an upper surface (except for a connection part to a after-mentioned drive circuit 5) of all the lower transparent electrodes 21; and an upper layer electrode 23 made of aluminum and the like and formed as a common layer on an upper surface of the organic luminous layer 22. In such configuration, an area on which the lower layer transparent electrode 21 overlaps with the upper layer electrode 23 is a light emitting area. Additionally, in FIG. 3, the organic luminous layer 22 between both electrodes is formed in a single layer structure, but it may be formed in a multi-layer structure with a hole transporting layer provided between the organic luminous layer 22 and the lower layer transparent electrode 21, and an electron transporting layer provided between the organic luminous layer 22 and the upper layer electrode 23.

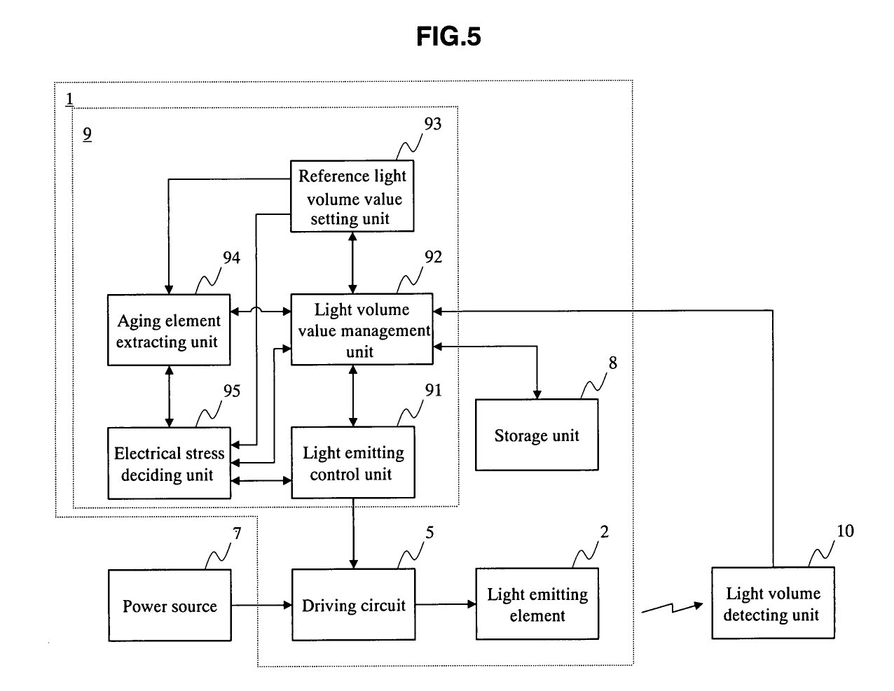

On the substrate S, each light emitting element 2 is provided with the drive circuit 5 for supplying electric power to the light emitting element to emit light, and the drive circuit 5 is formed by polysilicon TFT (Thin Film Transistor) and the like. According to a control signal inputted from an external for the electric power to be applied to each light emitting element 2 and the lighting time of each light emitting element 2, the drive circuit 5 applies the electric power supplied from an external power source 7 (in FIG. 5) to each light emitting element 2. In case of the electrophotographic apparatus provided with the exposure head 1, the control signal is prepared based on an image data formed as a latent image on the photoconductor 20. The control signal and the applied electric power are inputted from external connection terminals 6 as shown in FIG. 1 (it is omitted in FIG. 5).

The material of each member of the above-mentioned exposure head 1 is not limited in particular. But if each function can be carried out, it is possible to use an arbitrary material.

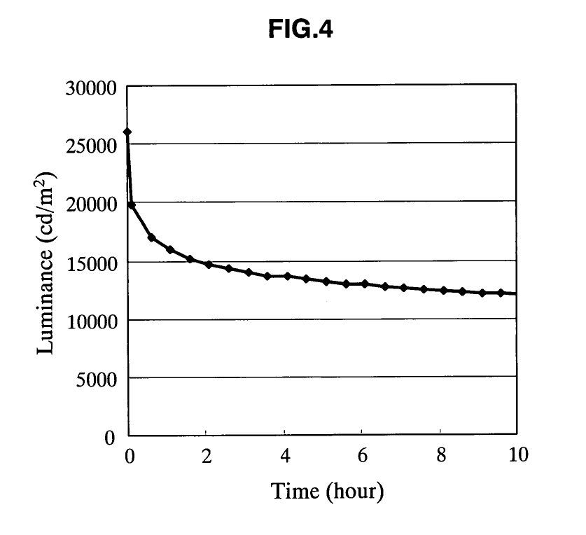

The organic EL element forming the light emitting element array 2 has characteristics that the luminance of the lighting reduces along with a power supplying time (the lighting time). FIG. 4 is a graph showing a change of the luminance of the organic EL element along with the power supplying time. In FIG. 4, a longitudinal axis indicates the power supplying time, while a vertical axis indicates the luminance.

As understood according to FIG. 4, the organic EL element reduces the luminance by the very short power supplying time at the initial period. Then, the luminance reduces gradually as compared with the reduction at the initial period of the power supplying. Using such characteristics, the electric power is supplied in a short time selectively to objective organic EL elements in the light emitting array 2, so that the luminance of such element can be reduced. That is to say, even if there is a dispersion of the luminance between the organic EL elements immediately after the manufacturing, the organic EL element with high luminance is selected and lighted by supplying power in a short time (which is called ‘aging’), and the high luminance of the organic EL element can be reduced. Therefore, by making the luminance of respective organic EL elements uniform over the whole light emitting array 2, the dispersion can be reduced.

For instance, to reduce the luminance by 10% at the initial period, the power supplying time is approximate 1 minute. If the life of the element ends when the luminance reaches at 50% of the initial luminance, the life of the element is about 10 hours according to FIG. 4. Therefore, 1 minute aging, which is equivalent to 1/600 of the element's life, does not shorten the life of the element extremely, and it is acceptable adequately from a practical standpoint.

The invention reduces the light volume dispersion by means of the characteristics of the organic EL element. The following explanation relates to the aging of the exposure head.

FIG. 5 is a schematic functional block diagram of the exposure head 1 of the invention. As shown in FIG. 5, the exposure head 1 of the invention that is configured as above is further provided with a storage unit 8 for storing a light volume value of each emitted light, and an aging unit 9 for giving a electrical stress (aging stress) to each light emitting element 2 respectively based on the light volume value stored in the storage unit 8. The aging unit 9 consists of CPU, a memory, and the like, which can be carried out by a software stored in the memory and executable by CPU. The aging unit 9 is provided with a light emitting control unit 91, a light volume value management unit 92, a reference light volume value setting unit 93, an aging element extracting unit 94 and an electrical stress deciding unit 95, as described hereinafter.

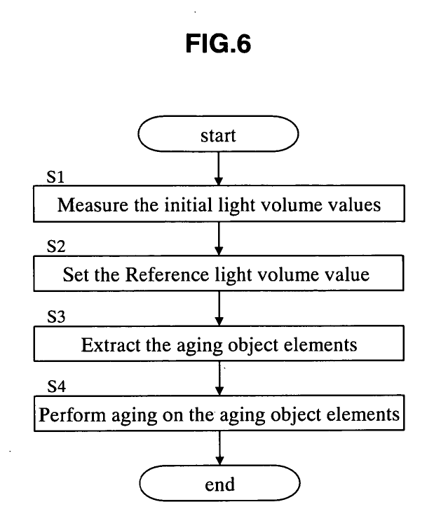

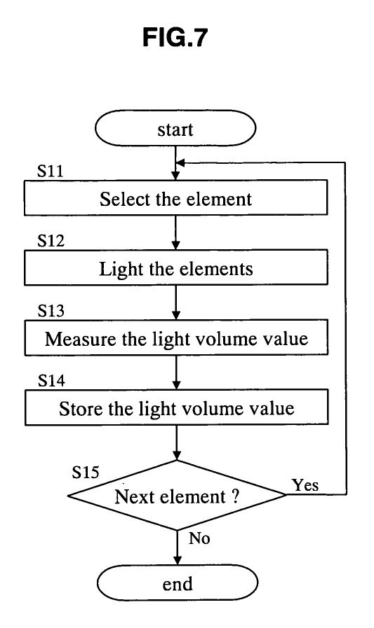

The details of the aging unit 9 are explained according to FIG. 5 to FIG. 10. FIG. 6 is a flowchart showing steps of the aging, and FIG. 7 to FIG. 10 are flowcharts for explaining details of respective steps S1 to S4 in FIG. 6. Besides, it is assumed in the following explanation that the drive circuit 5 of the exposure head 1 is connected to the external power source 7 through the external connecting terminals (see FIG. 1).

In Step S1 in FIG. 6 for measuring an initial light volume value, a light volume detecting unit 10, which is comprising photoelectric elements outputting the light volume value as a voltage value, is placed at a position focused the emitted light from the exposure head 1, and measures the initial light volume value of each emitted light.

In the step of measuring the initial light volume value (FIG. 6, S1), as shown in FIG. 5 and FIG. 7, the light emitting control unit 91 outputs a control signal for lighting the light emitting element 2 for a specific time by normal electric power (the electric power applied at the exposure of the photoconductor 20), and sends it to the drive circuit 5 of the light emitting element 2 mounted on an end of the exposure head 1 (FIG. 7, S11). The initial light volume value corresponding to the light emitting element 2 lighted by the control signal is outputted from the light volume detecting unit 10 as a voltage value (FIG. 7, S12 to S13), and then inputted to the light volume value management unit 92.

The light volume value management unit 92 stores in the storage unit 8 the initial light volume value associating the value with the light emitting element 2 that emitted the light (FIG. 7, S14). The step of measuring the initial light volume value is executed on all the light emitting elements of the exposure head 1 (FIG. 7, S15). A format of data to be stored in the storage unit 8 is not limited in particular, but in the embodiment, the storage unit 8 stores a pair of data consisting of an element number given to the light emitting element 2 in order based on a position on the exposure head 1 and an initial light volume value of the corresponding light emitting element 2. The light volume value to be stored in the storage unit 8 is not limited only to an output value from the light volume detecting unit 10, but it may be an adjustment coefficient (proportion or difference) on basis of a specific light volume value, for example.

As shown in FIG. 6, after the step S1 of measuring the initial light volume value, a step S2 of setting a reference light volume value is executed. In this step, the reference light volume value setting unit 93 sets the reference light volume value base on a specific initial light volume value to use to a next step S3 of extracting an aging element. In this embodiment, the reference light volume value setting unit 93 is configured to extract a minimum value of the initial light volume (a minimum light volume value) as the specific initial light volume value, and then set a value 1.22 times the minimum light volume value to the reference light volume value (‘1.22 times’ will be explained later).

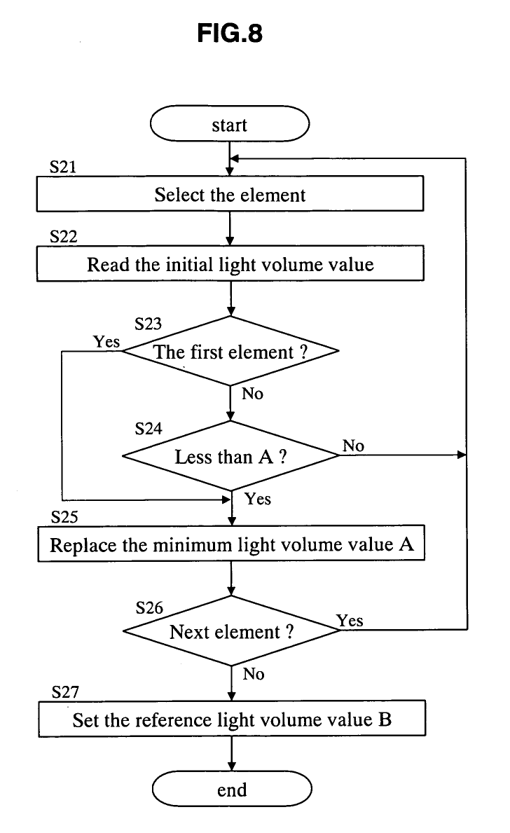

As shown in FIG. 5 and FIG. 8, in this step, the reference light volume value setting unit 93 reads one of the initial light volume values corresponding to the element number from the storage unit 8 through the light volume value management unit 92, and then provisionally stores the readout initial light volume value as the minimum light volume value A (FIG. 8, S21 to S22 to S23 ‘Yes’ to S25).

Subsequently, the reference light volume value setting unit 93 reads another of the initial light volume values corresponding to a next element number from the storage unit 8 (FIG. 8, S21 to S22), and then judges whether or not the initial light volume value is smaller than the minimum light volume value A (FIG. 8, S23 ‘No’ to S24).

If the initial light volume value is the minimum light volume value A or less, the reference light volume value setting unit 93 replaces the minimum light volume value A with the initial light volume value, and then reads the other initial light volume value corresponding to next element number, and performs the judging step S24 (FIG. 8, S24 ‘Yes’ to S25 to S26 ‘Yes’ to S24). On the other hand, where the initial light volume value is over the minimum light volume value A, the reference light volume value setting unit 93 does not replace the minimum light volume value A with the initial light volume value, and reads the other initial light volume value corresponding to next element number, and performs the judging step S24 (FIG. 8, S24 ‘No’0 to S26 ‘Yes’ to S24). Therefore, when all the initial light volume values stored in the storage unit 8 are subjected to the judging step S24, the reference light volume value setting unit 93 can stores the smallest initial light volume value of all the initial light volume values as the minimum initial light volume value A.

As described above, after extracting the minimum initial light volume value A from all the initial light volume values, the reference light volume value setting unit 93 sets a light volume value 1.22 times the minimum light volume value A to a reference light volume value B (FIG. 8, S27). Besides, in the embodiment, the reference light volume value setting unit 93 is configured so as to store the minimum light volume value A and the reference light volume value B, but those values may be stored in the storage unit 8.

After setting the reference light volume value B in such way, a step S3 of extracting an aging element is executed as shown in FIG. 6. In this step, the aging element extracting unit 94 specifies a light emitting element 2 corresponding to the initial light volume value over the reference light volume value B.

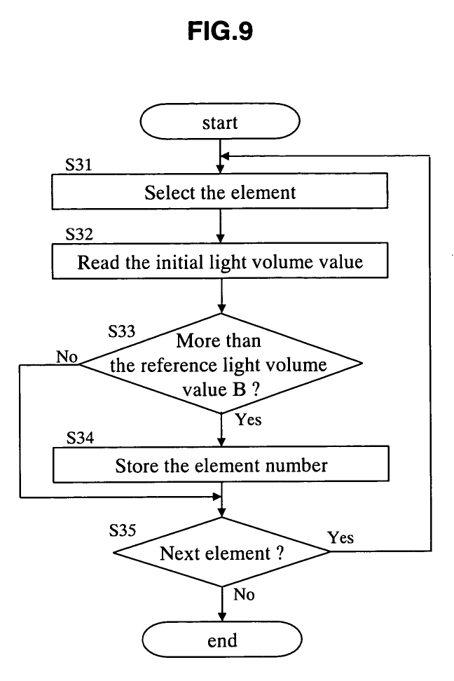

As shown in FIG. 5 and FIG. 9, the aging element extracting unit 94 reads out from the storage unit 8 the initial light volume value corresponding to the element number through the light volume value management unit 92, as well as reads the reference light volume value B from the reference light volume value setting unit 93 (FIG. 9, S31 to S32). It is judged whether or not the readout initial light volume value is over the reference light volume (FIG. 9, S33). Where the readout initial light volume is over the reference light volume B, the aging element extracting unit 94 stores the element number of the light emitting element 2 corresponding to the initial light volume value, and then reads another initial light volume value corresponding to next element number (FIG. 9, S33 ‘Yes’ to S34 to S35 ‘Yes’). In addition, where the readout initial light volume is the reference light volume value B or less, the aging element extracting unit 94 only reads the initial light volume value corresponding to next element number (FIG. 9, S33 ‘No’ to S35 ‘Yes’). Therefore, after completing the judging step 33 for all the initial light volume values stored in the storage unit 8 (FIG. 9, S35 ‘No’), the aging element extracting unit 95 stores a list of the light emitting elements corresponding to the initial light volume values over the reference light volume value B.

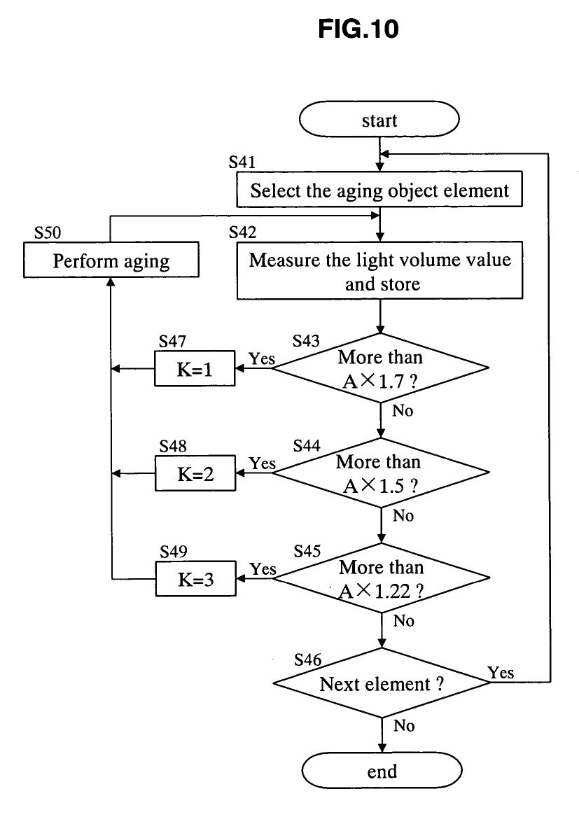

Accordingly, after the step S3 of extracting the aging element, a step S4 of the aging in FIG. 6 is executed. That is to say, as shown in FIG. 5 and FIG. 10, the electrical stress deciding unit 95 reads the reference light volume value B (or the minimum light volume value A) from the reference light volume value setting unit 93 and also reads the element number of an aging object element from the aging element extracting unit 94 (FIG. 10, S41).

Next, the electrical stress deciding unit 95 orders the light emitting control unit 91 to output a control signal for lighting the light emitting element 2 corresponding to the readout element number, and measures a latest light volume value of the aging object element. At this time, the lighting time of the light emitting element 2 may be the same as the lighting time at the step S1 of measuring the initial light volume value. In the embodiment, the light volume measuring is executed to confirm the latest light volume value of the aging object element, but instead of the light volume value measuring, the electrical stress deciding unit 95 may read the initial light volume value corresponding to the readout element number from the storage unit 8.

The light volume value corresponding to the light emitting element 2 lighted by the control signal is outputted as a voltage value by the light volume detecting unit 10, and the light volume value management unit 92 stores the value in the storage unit 8 together with the element number (FIG. 10, S42). At this time, the light volume value management unit 92 may delete the prior initial light volume stored in the storage unit 8. However, if the latest light volume can be distinguish from the others by a time stamp, for example, the storage unit 8 may store a plurality of data relevant to the same element number.

The electrical stress deciding unit 95 decide a value of flag K based on both the latest light volume value corresponding to the aging object element and the reference light volume value B (or the minimum light volume value A) set by the reference light volume value setting unit 93, and decides the electrical stress for the aging based on the value of flag K.

Specifically, as shown in FIG. 10, when the latest light volume value is over 1.7 times the minimum light volume value A, the electrical stress deciding unit 95 sets the value of flag K to 1 (FIG. 10, S43 ‘Yes’ to S47). On the other hand, when the latest light volume is 1.7 times the minimum light volume value A or less and over 1.5 times of the minimum light volume value A, the electrical stress deciding unit 95 sets the value of flag K to 2 (FIG. 10, S43 ‘No’ to S44 ‘Yes’ to S48). when the latest light volume value is 1.5 times the minimum light volume value A or less and over 1.22 times the minimum light volume A, the electrical stress deciding unit 95 sets the value of flag K to 3 (FIG. 10, S44 ‘No’ to S45 ‘Yes’ to S49).

The electrical stress deciding unit 95 gives the aging object element the electrical stress depending on thus decided value of flag K (FIG. 10, S50).

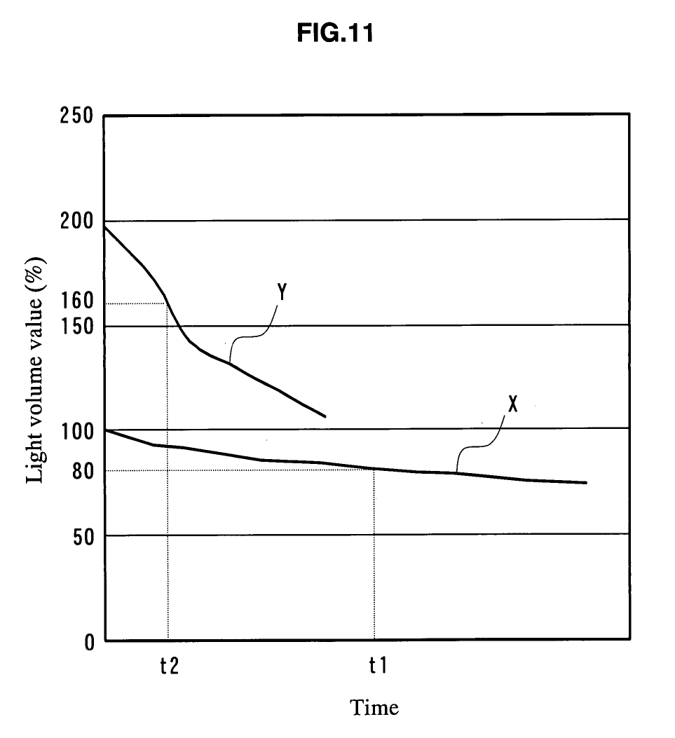

The aging effect is explained hereinafter according to FIG. 11. FIG. 11 shows the aging degradation of the light volume values in case of giving different electrical stresses to the light emitting element 2. A line X expresses the aging degradation of the light volume value in the normal aging (wherein the applied power is approximate the same as in actual use), and a line Y expresses another aging degradation of the light volume values in the aging giving with the electrical stress so that the light volume value becomes two times the initial light volume value at the normal supplying power. In FIG. 11, a vertical axis indicates a light volume value, and a longitudinal axis indicates a time.

Comparing the line X and the line Y, the time when the light volume value becomes 20% of the initial light volume vale is t1 on the line X and t2 on the line Y. The time t2 is one-fifth of the time t1. That is to say, where the aging is performed by giving the electrical stress larger than that of the normal aging, it is possible to shorten the time necessary for degrading the light volume value to a specific proportion. The aging can be accelerated by the electrical stress with the increased electricity application. That is to say, it is possible to perform the accelerated aging.

In the embodiment, the electrical stress deciding unit 95 selects one of electrical stresses predetermined based on the value of flag K; the electric power corresponding to a value two times the light volume value; the power corresponding to a value 1.5 times the light volume value; and the power corresponding to a value 1.2 times the light volume value. On the basis of the selected electrical stress, the electrical stress deciding unit 95 makes the light emitting control unit 91 output the control signal.

In case of K=1, the electrical stress deciding unit 95 makes the light emitting control unit 91 apply on the aging object element the power corresponding to a value 2 times the light volume value. In case of K=2, the electrical stress deciding unit 95 makes the light emitting control unit 91 apply on the aging object element the power corresponding to a value 1.5 times the light volume value. In case of K=3, the electrical stress deciding unit 95 makes the light emitting control unit 91 apply on the aging object element the power corresponding to a value 1.2 times the light volume value.

At this time, the time for applying the electrical stress may be a fixed time predetermined per each the electrical stress, or a specific time changed at the aging depending on the difference between the latest light volume value of the aging object element and the reference light volume value B. For instance, if the time-dependent data of the light volume value degradation per each the electrical stress, wherein the relation between the light volume value and the degradation time is indicated depending on the electrical stress, is obtained in advance, the time for applying each the electrical stress may be a time for decreasing the light volume value by 20%, or a time for decreasing the light volume value by a proportion corresponding to the difference between the latest light volume value and the reference light volume value B.

The aging is performed by giving a different electrical stress based on the difference between the light volume value and the reference light volume value B (or the minimum light volume value A) in such way, so that the efficient aging can be performed in short time.

After completing the aging as mentioned above, the electrical stress deciding unit 95 measures the light volume value of the aging object element once more (FIG. 10, S42). According to the measured light volume value, the electrical stress deciding unit 95 decides the electrical stress and performs the aging of the aging object element, once more.

The above mentioned steps are iterated till the aging object element has a target light volume value (the reference light volume value B or less). When the light volume reaches the target light volume value (FIG. 10, S45 ‘No’), the electrical stress deciding unit 95 terminates the aging of the aging object element and then starts the next aging for another aging object element.

After aging all of the aging object elements, the whole light volume values of the exposure head 1 ranges from the minimum light volume value A as a lower limit to the reference light volume value B (1.22 times the minimum light volume value) as an upper limit.

Since the upper limit is defined as a value 1.22 times the lower limit in the embodiment, the whole light volume values of the aged exposure head 1 ranges from the upper limit set by a value raise of 10% of the median of the above range to the lower limit set by a value down by 10% of the median of the above range.

The above explanation is based on a configuration that the electrical stress to be applied to the light emitting element according to the light volume value is selected from three levels of a stress to make the light volume value 2 times, a stress to make the light volume value 1.5 times, and a stress to make the light volume value 1.2 times. Such configuration is only an embodied example, and does not limit the aging of the present invention. The upper limit of the electrical stress may be set to a value over 2 times as far as it is not beyond a limit depending on the aging object element (a maximum rating of voltage or current density), or may be selected from multi levels of stresses.

The amount of the electrical stress does not involve being set to specific times the light volumes. Regardless the light volume, the amount of the electrical stress may be decided only by changing any of a voltage and a current, or both of them.

In other words, the aging may reduce the electrical stress as the difference between the latest light volume value and the reference light volume value got smaller. In such case, even in any method of giving the electrical stress, it is possible to perform the appropriate aging to obtain the target light volume value.

Furthermore, when the exposure head is aged, the ambient temperature is not limited in particular, for example, the aging can be performed at room temperature. To accelerate the aging, the aging may be performed at a temperature at which heating may not damage the light emitting element.

The above aging is for applying voltage (current) as an electrical stress in order to degrade the light volume of the aging object light emitting element. That is to say, in case of an element with rectifying property like the organic EL element, the voltage (current) is applied in a forward direction.

Generally, when the voltage (current) is applied on the element with rectifying properties like the organic EL element in a reverse direction (reverse bias application), the resistance of the element to the degradation can be improved. The aging can be performed together with the reverse bias application.

For instance, where the reverse bias is applied on the aging object element, the speed of reducing the light volume is made slow due to the application of the reverse bias, even in the same electrical stress. Therefore, when the latest light volume value of the aging object element is close on the target value, the reverse bias is applied on the aging object element one or plural times for a specific period interrupting the aging. Therefore, this makes it easy to adjust the degradation of the light volume value near the target light volume value. That is to say, it is possible to adjust the light volume of the aging object light emitting element to the upper limit of the target light volume value exactly. The specific period in this step is a time necessary for obtaining an effect that the degradation resistance is improved by means of the reverse bias application. Additionally, the specific period will change by the voltage (current) to be applied as the reverse bias or an element structure, but the time may be predetermined based on the time-dependent data obtained in advance.

Since the reverse bias application can improve the degradation resistance of the light emitting element, the reverse bias is preferably applied on all the light emitting elements. Therefore, as described above, it is desired that, when the reverse bias is applied together with the aging, after completing the aging for all the aging object elements, the reverse bias is applied on the excluded elements for the specific period.

As described above, in the exposure head of the invention, the aging can be performed selectively on the light emitting element based on the initial light volume value of the emitted light. Accordingly, it is possible to obtain the exposure head with small light volume dispersion. In result, the exposure head needs not to be provided with a correction circuit for controlling respective light volume values of the light emitting elements like conventional exposure heads, and the drive circuit 5 of the light emitting element 2 can be configured in a simple structure.

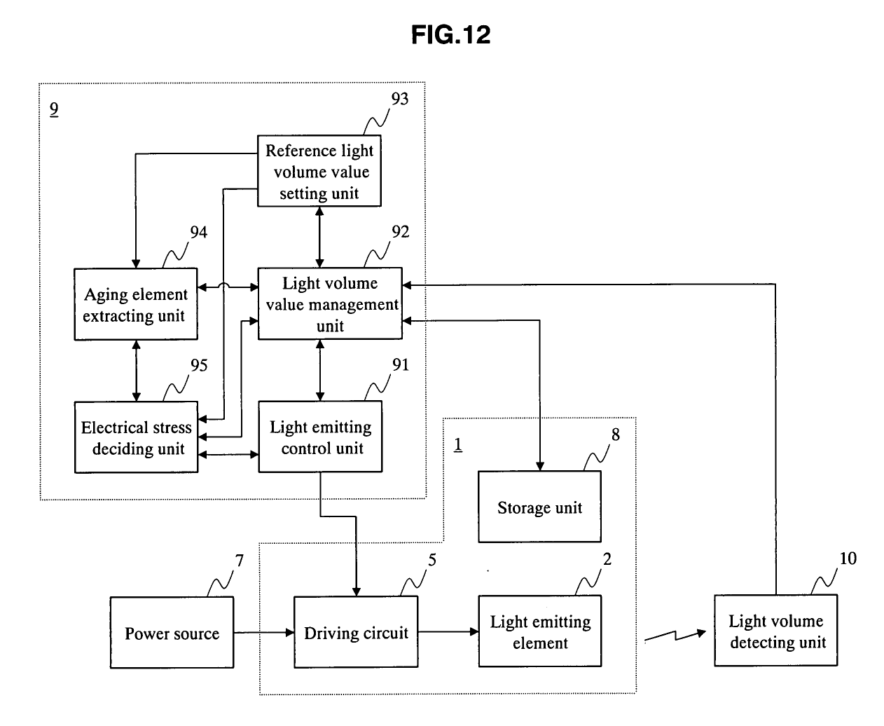

In the above configuration, the exposure head 1 is provided with the aging unit 9. However, the aging unit 9 can be provided to an outside of the exposure head 1, and perform the aging on the exposure head 1, as shown in FIG. 12. In such case, it is also possible to obtain the same effect. Besides, the aging unit 9 may be provided with the drive circuit for driving each light emitting element 2, and perform the aging without using the drive circuit 5 on the exposure head 1. Such configuration makes it possible to perform the aging, even when the drive circuit 5 is not provided to the exposure head 1. In another modified embodiment, the storage unit 8 can be provided to an outside of the exposure head 1, but the storage unit is preferably provided to the exposure head 1 to achieve the object of making it easy to adjust the light volume of the exposure head during use, which will be explained later.

In the above embodiment, each step is performed for one of the aging object elements, but each step may be performed for a plurality of the aging object elements at a same time.

Besides the reference light volume value and the target light volume value (the permissible range) are set based on the minimum light volume value A of the exposure head 1, as mentioned above. However, if it is possible to reduce the light volume dispersion of the exposure head 1, those values may be set arbitrarily. For example, without using the minimum initial light volume value A, the reference light volume value and the target light volume value may be set by using a predetermined light volume value (which is called a lower limit light volume value), and a light volume value not less than and nearest to the lower limit light volume value in each light volume value of the exposure head 1. The light volume value not less than and nearest to the lower limit light volume value can be extracted by set ‘not less than the lower limit light volume’ to an extracting condition at the step of extracting the minimum light volume value A.

Even when the reference light volume value and the target light volume value are set in such way, the aging is performed on the light emitting elements with the light volume value larger than the reference light volume value. Accordingly, the light volume dispersion of the exposure head 1 can be reduced. In this case, the light volume values smaller than the lower limit light volume value are not considered in the reducing of the light volume dispersion. However, if the lower limit light volume value is defined to the light volume value near to the lower limit of the light volume dispersion caused by the normal manufacturing dispersion in the manufacturing process of the exposure head 1, it is possible to reduce the light volume dispersion as well as the reference light volume value and the target light volume value are defined based on the minimum initial light volume.

Moreover, the minimum light volume value A was defined by the lower limit of the target light volume value in the above, but it needs not be the lower limit. Even when the aging is performed according to the target light volume value that is the permissible range wherein the minimum light volume value A is set to the median, it is possible to obtain the same effect.

The above description relates to the method of reducing the light volume dispersion of the exposure head integrated with the light emitting elements, however, the exposure head 1 can be mounted with the light emitting element array 2 formed separately. In this case, the aging can be performed when electric power can be applied to the light emitting elements of the light emitting array 2 in the manufacturing process. Otherwise, the aging can be performed for a period after the light emitting array is completed until it is mounted with the exposure head.

By such configuration, the exposure head 1 having the small light volume dispersion can be assembled using the light emitting array 2 of which light volume (luminance) dispersion is reduced by the aging, and the manufacturing yield of the exposure head 1 having the small light volume dispersion can be improved. Therefore, it is possible to manufacture the exposure head and the electrophotographic apparatus at a low cost.

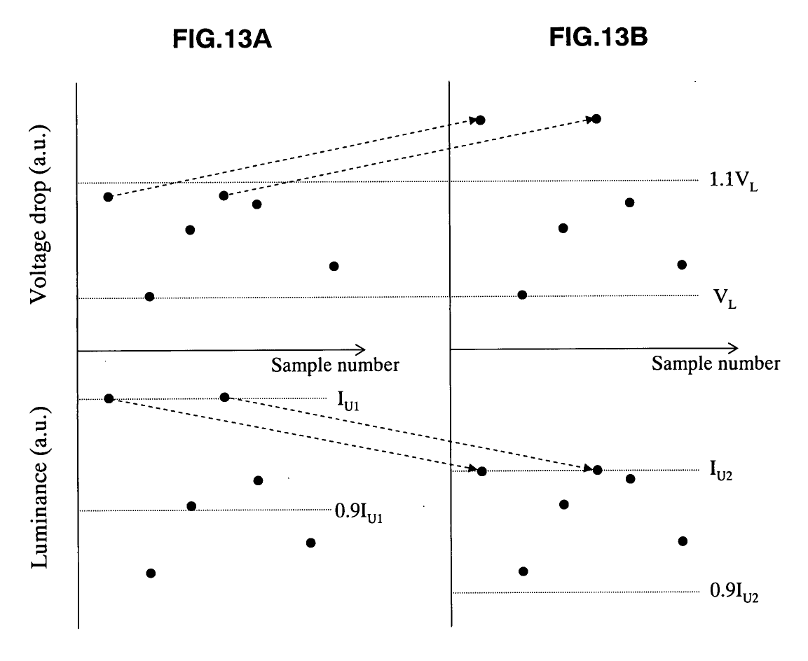

Here is explained about characteristics of the light emitting array that is subjected to the aging. FIGS. 13A and 13B are a diagram showing the voltage drop and the luminance of the light emitting element on which the same current is supplied. In FIG. 13A shows a state before the aging, and FIG. 13B shows a state after the aging.

As shown in FIG. 13A, the light emitting array integrated with a plurality of light emitting elements has the very small characteristic dispersion between the light emitting elements, because of the same manufacturing conditions. However, the luminance dispersion of the light emitting elements becomes large, because the dispersion of the luminous efficacies of the light emitting elements becomes relatively large. To put it concretely, in FIG. 13A, there is no light emitting element with a voltage drop more than a raise of 10% of a minimum value V_{L} Of the voltage drops (1.1V_{L}), and there is a light emitting element with a luminance smaller than 90% of a maximum value I_{U1} of the luminances (0.9I_{U1}).

Where the aging is performed on such light emitting array so that each luminance of the light emitting elements becomes more than 90% of the maximum value I_{U2} of the luminance after the ageing, all the luminances of the light emitting elements becomes more than 90% of the maximum value I_{U2} of the luminance after the ageing (that is, 0.9I_{U2}), as shown in FIG. 13B. At this time, the voltage drop of the aged light emitting element increases, and becomes more than 110% of the minimum voltage drop of the voltage drops after the aging (1.1L_{V}). In this way, the light emitting element array after the aging has characteristics that there are light emitting elements wherein all the luminances of each the light emitting elements when a same current is supplied to each the element is 90% and more of a maximum value of the luminances. And a plurality of the voltage drops when a same current is supplied to each the element is 110% and more of a minimum value of all the voltage drops.

In other words, the light emitting array has a feature that, when the same current is supplied to each the light emitting element, a standard deviation of the voltage drops of all the elements divided by a mean value of the voltage drops is larger than a standard deviation of the luminances of all the elements divided by a mean value of the luminances.

Therefore, the light emitting array with the above feature has been performed the above aging for the luminance adjustment and can be used as the aged one.

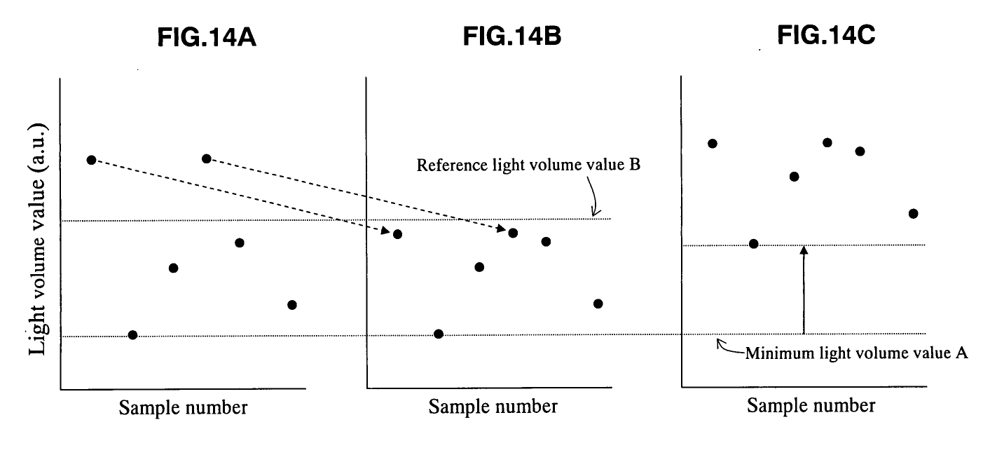

Meanwhile, after the above-mentioned aging is performed on the light emitting elements with the initial light volumes larger than the reference light volumes, the light volume dispersion of the exposure head 1 changes from the state as shown in FIG. 14A, the large light volume dispersion, to the state as shown in FIG. 14B, the small light volume dispersion. The light volume values of all the emitted light is included in the permissible range set based on the initial light volume value of specific emitted light, that is to say, ranges from the minimum light volume A to the reference light volume B that is 1.22 times the minimum light volume A.

However, since the minimum light volume A is generally different per exposure head 1, the permissible range set based on the minimum light volume A is not always an appropriate range for forming a latent image on the photoconductor 20. That is to say, it is predicted that the light volume of the exposure head 1, of which light volume dispersion is reduced by the aging, will become too large overall in comparison with the appropriate light volume, or become too small overall.

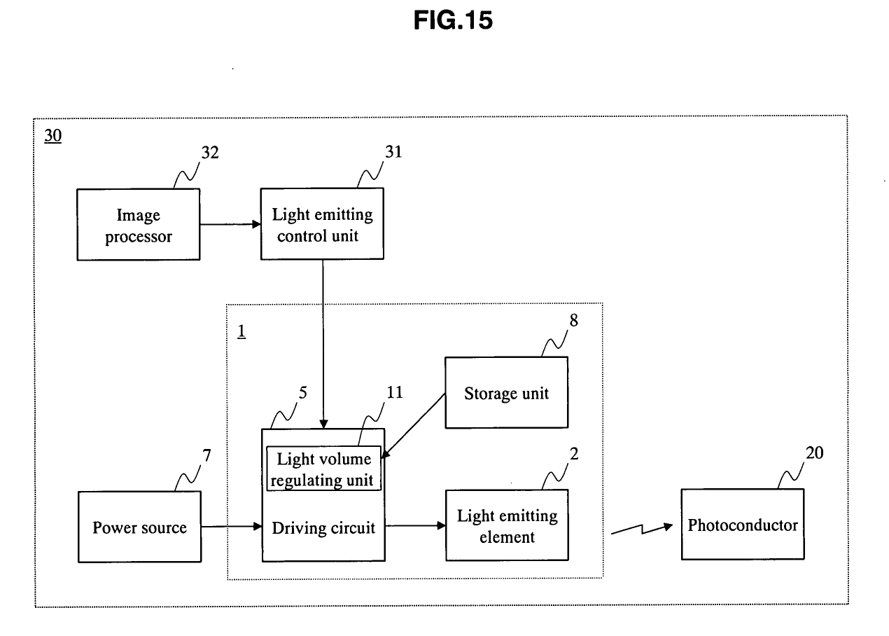

Therefore, the exposure head 1 is preferably provided with a light volume regulating unit 11 for regulating each light volume of light emitted from the exposure head 1, according to need, by varying all the light volumes of the emitted light to one direction, specifically, by increasing or reducing all the light volumes all at once, for example. FIG. 15 is a schematically functional block diagram of an electrophotographic apparatus 30 provided with the exposure head 1 shown in FIG. 12.

As shown in FIG. 15, a control signal, which is generated by a light emitting control unit 31 on the basis of an image data outputted from an image processor 32, is inputted to the drive circuit 5 of the exposure head 1. The light volume regulating unit 11 can be configured a part of the drive circuit 5 for a circuit shifting a specific quantity of current or voltage to be applied to each light emitting element 2 over all the elements, for example. As shown in FIG. 14C, the light volume regulating unit 11 regulates the light volume of each emitted light to be an appropriate light volume for forming a latent image on the photoconductor 20 on the basis of the minimum light volume A stored in the storage unit 8 and a user's instruction inputted by an input unit not shown in the drawing. Accordingly, the configuration with the light volume regulating unit 11 makes it possible to regulate further the light volume of the exposure head 1 of which light volume dispersion was reduced to be suitable for a print process.

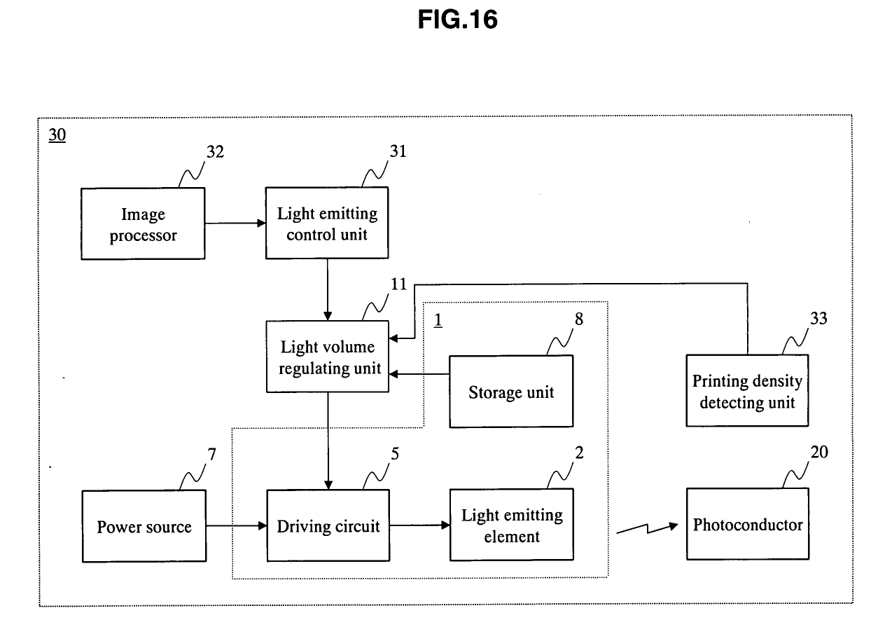

Additionally, the light volume regulating unit 11 may be mounted to the electrophotographic apparatus 30 with the exposure head 1, as shown in FIG. 16. In this case, the electrophotographic apparatus 30 is further provided with a printing density detecting unit 33 for outputting a signal corresponding to a printing density of a test pattern formed on a paper, for example, and the light volume regulating unit 11 preferably regulates each light volume of all the emitted lights on the basis of the minimum light volume A stored in the storage unit 8 and the signal sent from the printing density detecting unit 33.

Even when there are individual differences (sensitivities) between the optimum exposure light volumes of light to irradiate the photoconductor 20 due to the manufacturing dispersion, the above configuration makes it possible to easily regulate the light volumes considering the individual differences of the photoconductors, in addition to the above-mentioned effect and action. In other words, the light volume that the light volume regulating unit 11 regulates on the basis of the minimum light volume A stored in the storage unit 8 is a standard light volume predicted to be appropriate, and when the optimum exposure light volume for the photoconductor 20 is larger than the standard light volume due to the manufacturing dispersion, the exposure light volume is short. Therefore, the light volume regulating unit 11 further regulates the light volume on the basis of a printing density detected by the print density detecting unit 33. This makes it possible to easily regulate the light volume corresponding to the optimum exposure light volume for the photoconductor 20.

Besides, the electrophotographic apparatus 30 is not always provided with the printing density detecting unit 33, and the light volume regulating unit 11 may regulate the light volume according to an instruction based on an output result of an image inputted by a user from an input unit not illustrated in the drawing. The light volume regulating unit 11 may be a circuit for varying a specific quantity of a lighting time of each light emitting element, or may be configured by software executed on CPU.

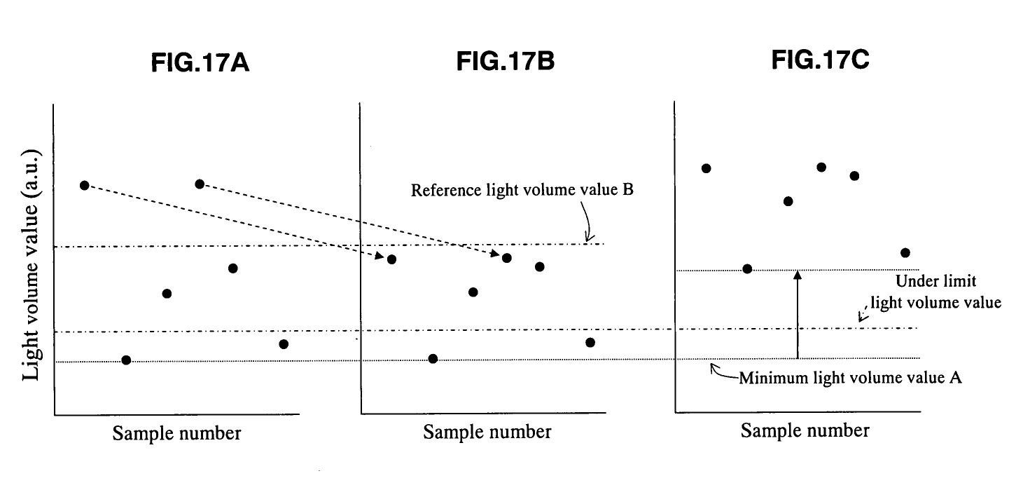

As described above, even if the reference light volume value and the target light volume value are set on the basis of the predetermined lower limit light volume value or the light volume value more and nearest to the lower limit light volume value, the light volume regulating unit 11 works in the same way. Likewise inn this case, all the emitted light of the exposure head 1 are in the range from the minimum light volume value to the reference light volume value, as shown in FIG. 17B (from state as shown in FIG. 17A). Accordingly, the light volume regulating unit 11 can regulate the light volume appropriate to the printing in the same way as shown in FIGS. 14A to 14C, by shifting the minimum light volume to the appropriate light volume for forming the latent image on the photoconductor 20 as shown in FIG. 17C. Besides, if the difference between the minimum light volume and the lower limit light volume (or the light volume nearest to the lower limit light volume) can be considered as a non-controversial difference for the printing, the light volume regulating unit 11 may regulate all the light volumes to appropriate light volumes for forming the latent image on the basis of those specific light volumes.

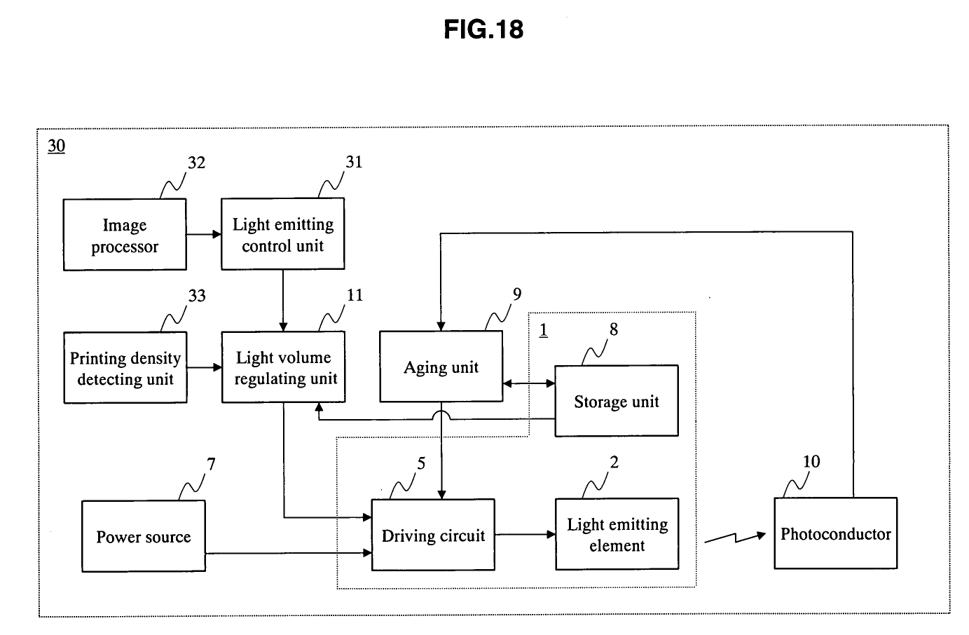

In the above, the aging is performed at assembling the exposure head 1. However, the aging may be performed on the exposure head after working normally; that is to say, it may be performed on the exposure head provided to the electrophotographic apparatus 30. FIG. 18 is a functional block diagram of the electrophotographic apparatus carrying out this aging.

As shown in FIG. 18, the electrophotographic apparatus 30 is provided with the light volume detecting unit 10 acquiring the light volumes of the emitted light from the exposure head 1 and the aging unit 9.

Even if the light volume dispersion of the exposure head 1 is reduced by the aging, since the exposure head 1 is mounted to the electrophotographic apparatus 30 and used, each element degrades gradually according to the lighting conditions. If all the light emitting elements have the same lighting time, a degree of the light volume degradation varies in degree due to the individual difference of light emitting element. In result, the light volume dispersion of the light becomes large.

Under such condition, the electrophotographic apparatus 30 in FIG. 18 is configured so that the light volume detecting unit 10 measures the light volume of each light emitted from the exposure head 1 and stores the value in the storage unit 8 when the aging is instructed by the user. The light volume detecting unit 10 may be formed by a photoelectric element, and it is retractably intervened between the exposure head 1 and the photoconductor 20 so as to obtain the light volumes of light emitted from the exposure head 1.

Then, based on the light volumes of emitted light stored in the storage unit 8, the aging unit 9 performs the aging on the exposure head 1. In this way, in result of the aging for reducing the light volume of the light emitting element corresponding to a large light volume, the light volume dispersion of the exposure head 1 can be reduced. Besides, since the measuring step for the light volume value and the aging are the same as described above, the explanation is not made here.

As described above, in case of applying the invention, it is possible to uniform the light volume of the exposure head 1 of which light volume dispersion increases due to a use. In FIG. 18, the exposure head 1 is provided with the storage unit 8, however, if the storage unit 8 can store the light volumes of light from the exposure head 1, it may be placed at any position.

The above mentioned embodiments do not limit the technical field of the invention, and the invention can be modified and put to practical use within the scope of the invention, except for the above disclosure.

1. A manufacturing method of forming a light emitting element array by integrating a plurality of light emitting elements that emit light by supplying power respectively, the method comprising:
measuring a luminance of each light emitting element; and
degrading the luminance of the light emitting element selected based on the measured luminance by giving a electrical stress only to the selected light emitting element.

2. A luminance adjustment method of adjusting a luminance of a light emitting element array formed by integrating a plurality of light emitting elements that emit light by a supplying power respectively, the method comprising:
measuring a luminance of each light emitting element; and
degrading the luminance of the light emitting element selected based on the measured luminance by giving a electrical stress only to the selected light emitting element,
wherein the luminance of each light emitting element is adjusted within a specific range.

3. A light emitting element array formed by integrating a plurality of light emitting elements that emit light by supplying power respectively, including light emitting elements of which all luminances emitted with a same current application is 90% and more of a maximum value of all the luminances, and of which a plurality of voltage drops with the same current application is 110% and more of a minimum value of all the voltage drops.

4. A light emitting element array formed by integrating a plurality of light emitting elements that emit light by supplying power respectively, wherein, when a same current is applied on the light emitting elements, a standard deviation of voltage drops at each the element divided by a mean value of the voltage drops is larger than a standard deviation of luminances of the elements divided by a mean value of the luminances.

5. An exposure head for irradiating light on a photoconductor and forming a latent image thereon, comprising the light emitting array according to claim 2.

6. An exposure head for irradiating light on a photoconductor and forming a latent image thereon, comprising the light emitting array according to claim 3.

7. An electrophotographic apparatus for performing an image forming based on a latent image formed on a photoconductor, comprising the light emitting array according to claim 5.

8. An electrophotographic apparatus for performing an image forming based on a latent image formed on a photoconductor, comprising the light emitting array according to claim 6.

9. An exposure head for emitting respectively light generated from a plurality of light emitting elements, comprising:
a storage unit configured to store light volume values of each emitted light; and,
an aging unit configured to giving per light emitting element corresponding to the emitted light a electrical stress to degrade the light volume of the light emitting element based on the light volume value stored in the storage unit.

10. An exposure head according to claim 9, wherein the aging unit gives the electrical stress only to the light emitting element corresponding to the emitted light with the light volume value larger than a reference light volume value set based on a specific light volume value.

11. An exposure head according to claim 10, wherein the specific light volume value is a minimum light volume value on the exposure head.

12. An exposure head according to claim 10, wherein the specific light volume value is a predetermined light volume value.

13. An exposure head according to claim 10, wherein the specific light volume value is not less than a predetermined light volume value and nearest to the predetermined light volume value.

14. An exposure head according to claim 9, the aging unit performs an accelerated aging.

15. An exposure head according to claim 10, the aging unit performs an accelerated aging.

16. An exposure head according to claim 14, wherein the accelerated aging is performed by increasing one or both of a current and a voltage to be applied to the light emitting element.

17. An exposure head according to claim 15, wherein the accelerated aging is performed by increasing one or both of a current and a voltage to be applied to the light emitting element.

18. An exposure head according to claim 10, wherein the aging unit defines as a target light volume value the light volume value within a permissible range set in advance based on the specific light volume value, and gives the electrical stress.

19. An exposure head according to claim 18, wherein the specific light volume value is a median or a lower limit in the permissible range.

20. An exposure head according to claim 18, further comprising a light volume regulating unit configured to regulate the light volume values of all the light emitting elements based on the specific light volume value.

21. An exposure head according to claim 19, further comprising a light volume regulating unit configured to regulate the light volume values of all the light emitting elements based on the specific light volume value.

22. An exposure head according to claim 20, wherein the light volume regulating unit shifts a specific quantity of the current or the voltage to be applied to all the light emitting elements base on the specific light volume value.

23. An exposure head according to claim 21, wherein the light volume regulating unit shifts a specific quantity of the current or the voltage to be applied to all the light emitting elements base on the specific light volume value.

24. An exposure head according to claim 20, wherein the light volume regulating unit shifts a specific quantity of the lighting time of all the light emitting elements based on the specific light volume value.

25. An exposure head according to claim 21, wherein the light volume regulating unit shifts a specific quantity of the lighting time of all the light emitting elements based on the specific light volume value.

26. An exposure head according to claim 9, wherein the light emitting element is an organic electroluminescence element.

27. An electrophotographic apparatus for performing the image forming based on a latent image formed by an exposure head for emitting respectively light generated from a plurality of light emitting elements, comprising:
a light volume regulating unit configured to regulate light volumes of all the light emitted from the exposure head, according to need, based on a specific light volume value.

28. An electrophotographic apparatus according to claim 27, wherein the specific light volume value is a minimum light volume value on the exposure head.

29. An electrophotographic apparatus according to claim 27, wherein the specific light volume value is a predetermined light volume value.

30. An electrophotographic apparatus according to claim 27, wherein the specific light volume value is not less than a predetermined light volume value and nearest to the predetermined light volume value.

31. An electrophotographic apparatus according to claim 27, wherein the light volume regulating unit shifts a specific quantity of the current or the voltage to be applied to all the light emitting elements base on the specific light volume value.

32. An electrophotographic apparatus according to claim 27, wherein the light volume regulating unit shifts a specific quantity of the lighting time of all the light emitting elements based on the specific light volume value.

33. An electrophotographic apparatus according to claim 27, wherein the light volume regulating unit regulates the light volume values of all the light emitting elements based on the specific light volume value and an image forming result.

34. An electrophotographic apparatus according to claim 33, further comprising:
a light volume detecting unit configured to detect the light volume value of each emitted light of the exposure head; and
an aging unit configured to giving per light emitting element corresponding to the emitted light a electrical stress to degrade the light volume value of the light emitting element based on the light volume value detected by the light volume detecting unit.

35. A manufacturing method of an exposure head emitting respectively light generated by a plurality of light emitting elements, the method comprising:
measuring the light volume of each emitted light; and
giving per light emitting element corresponding to the emitted light a electrical stress to degrade the light volume value of the light emitting element based on the measured light volume value.

36. A manufacturing method of an exposure head according to claim 35, wherein the electrical stress is given only to the emitted light with the light volume value larger than a reference light volume value set based on a specific light volume value.

37. A manufacturing method of an exposure head according to claim 36, wherein the specific light volume value is a minimum light volume value on the exposure head.

38. A manufacturing method of an exposure head according to claim 36, wherein the specific light volume value is a predetermined light volume value.

39. A manufacturing method of an exposure head according to claim 36, wherein the specific light volume value is not less than a predetermined light volume value and nearest to the predetermined light volume value.

40. A manufacturing method of an exposure head according to claim 35, wherein the electrical stress is the accelerated aging.

41. A manufacturing method of an exposure head according to claim 36, wherein the electrical stress is the accelerated aging.

42. A manufacturing method of an exposure head according to claim 40, wherein the accelerated aging is performed by increasing one or both of a current and a voltage to be applied to the light emitting element.

43. A manufacturing method of an exposure head according to claim 41, wherein the accelerated aging is performed by increasing one or both of a current and a voltage to be applied to the light emitting element.

44. A manufacturing method of an exposure head according to claim 36, further comprising a step of giving the electrical stress by defining as a target light volume value the light volume value within a permissible range set in advance based on the specific light volume value.

45. A manufacturing method of an exposure head according to claim 44, wherein the specific light volume value is a median or a lower limit of the permissible range.

46. A manufacturing method of an exposure head according to claim 35, wherein the light emitting element is an electroluminescence element.
